(19) United States
(12) Patent Application Publication
(10) Pub. No.: US 2016/0014914 A1
(43) Pub. Date: Jan. 14, 2016

(54) FLEXIBLE ELECTRONIC DEVICE HOUSING

(71) Applicant: Christian Stroetmann, Moers (DE)

(72) Inventor: Christian Stroetmann, Moers (DE)

(21) Appl. No.: 14/794,257

(22) Filed: Jul. 8, 2015

(30) Foreign Application Priority Data
Jul. 9, 2014 (DE) 20-2014-103-159.6

(51) Int. Cl. H05K 5/00; H05K 5/02

(52) U.S. Cl. CPC H05K 5/0021; H05K 5/0217

(57) ABSTRACT

A flexible housing for electronic devices mounted on or contained within the housing is disclosed that features a relatively simple but nonetheless elaborated and functional foldable means or joint means. Depending on the special way of construction, dimensions, and features of the joint means elements the flexible housing permits the folding of the housing even with a large curvature radius without putting pressure and stress on a flexible respectively bendable electronic device mounted on or contained within the housing, such as a flexible display device and a flexible computing device for example. Moreover, the flexible housing prevents to go below the maximum permissible curvature radius of an installed flexible respectively bendable electronic device. Therefore on the one hand stretching, compressing or even breaking an electronic device is avoided and on the other hand easier and safer ways to transport and store relatively large flexible electronic devices are given. In some embodiments the flexible housing also provides an adjustment means.

### CROSS-REFERENCE TO RELATED APPLICATION

This application claims the benefit of the German Utility Model Application No. 20-2014-103-159.6, filed Jul. 9, 2014, and entitled “Gerätegehäuse, das eine Befestigungsmöglichkeit für eine flexible beziehungsweise biegbare Anzeige and mindestens zwei Gehäuseteile hat, die durch ein Gelenk/Scharnier verbunden sind”, which is hereby incorporated by reference in its entirety.

### BACKGROUND

1. Field of the Dislosure

The present application relates generally to flexible housings of electronic devices. More particularly, the present invention pertains to flexible housings or cases comprising at least two segments, which are connected to each other by a joint or hinge means, a means for mounting a flexible display device, and an adjustment means to ease the usage, transportation, and storage of flexible electronic devices.

2. Description of the Related Art

In some disclosures electronic devices are described that have a flexible housing or case.

In U.S. Pat. No. 4,412,751, issued Nov. 1, 1983, and entitled “Jointed electronic watch”, a wristwatch is disclosed that has a solid watch face and a solid display device contained in two corresponding housing parts or segments, which are connected to each other by a joint or hinge means. The housing also comprises a bellows member, which is not part of the joint or hinge means, but provides protection against dust and moisture. The curvature or bending radius is defined by the shape of the two connected housing parts and a sealing, which functions as a hinge band somehow. Furthermore, the device can only be bent in one direction starting from the completely flat out configuration and only with a very limited pivoting angle.

In U.S. Pat. No. 7,450,107, issued Nov. 11, 2009, and entitled “Bracelet with information display and inputting capability”, a wearable computer in the shape of a bracelet is disclosed, which has multiple segments with solid display screens arranged on the outer faces of these segments. The segments are connected by hinges and kept in position by the hinges or an adjustment means with locking means. The flexible housing could be scaled to the dimension required for a specific electronic device, but would provide only a larger curvature or bending radius that might be impractial for many applications. Furthermore, an additional means is needed to support and protect a flexible electronic device, such as a continues flexible display device arranged on the outer faces of the segments, from overstress or/and breaking due to the sharp edges that adjacent segments exhibit in bent configurations.

In U.S. Pat. No. 6,307,751, issued Oct. 23, 2001, and entitled “Flexible circuit assembly”, a device with a flexible circuit is disclosed that has a flexible foam rod displaced along the primary hinge area to keep the flexible circuit from being folded too sharply when the device is in its closed respectively folded configuration. Also claimed is a flexible display screen that may travel over a flexible substrate attached to the flexible display screen, thereby allowing at least one flexible substrate to be flexed without putting stress on the flexible display screen. Such a device depends on at least one layer of flexible substrate with conductive material deposited on.

However, still not all problems have been solved with such flexible electronic devices and accordingly several areas of technical problems and general demands have been determined, which can be solved with a housing for flexible devices that does not depend on only flexible electronic components, but also allows the possibility to use solid hardware components for the construction of a device, provides a small curvature or bending radius and a large angle of rotation, supports and protects the flexible electronic components against damages, and makes housing constructions possible that have a more aesthetical appearance.

### BRIEF SUMMARY

In accordance with the purpose of the invention, the invention pertains to a flexible housing or case for electronic devices, such as a display device and a computing device for example. The disclosed flexible device housing features a relatively simple but nonetheless elaborated and functional foldable means or joint means, which is based on different types of hinges. Depending on the special way of construction, dimensions, and features of the joint means elements the flexible housing can be folded even with a large curvature radius without putting pressure and stress on a flexible respectively bendable electronic device mounted on or contained within the housing. Moreover, the flexible housing prevents to go below the maximum permissible curvature radius of an installed flexible respectively bendable electronic device, specifically of a flexible display device. Therefore, on the one hand stretching, compressing, or even breaking an electronic device is avoided, and on the other hand easier and safer ways to transport and store relatively large flexible electronic devices are given. In some embodiments the flexible housing also provides an adjustment means.

The basic flexible device housing comprises at least two segments for housing solid and flexible electronic components and at least one joint means for connecting adjacent housing segements. A single joint means comprises two support elements with a first side and a second side, with the first side being opposite to the second side and being the side of the mounting means for a flexible display deivce, and a third element, which is a foldable means. The two support elements are connected at their first sides by a hinged means and at their second sides by the third foldable element. The housing segments can also be joint means themselves to realize a completely flexible housing.

Several embodiments of the present invention provide different basic types of the hinged means connecting the support elements and of the third element including a flexible material, a folding hinge, a folding piano hinge, and a living hinge or film hinge, and different type of joint means elements that assure a sealed passage of conductors from one segment to another segment of the flexible device housing. Furthermore, some embodiments provide an adjustment means to keep the flexible housing in at least one configuration.

Depending on its dimensions and features, the flexible device housing can be used for the construction of flexible electronic devices, such as a visual display, a loudspeaker, a wearable computer, specifically a smartwatch, a mobile/cell phone, specifically a smartphone, a tablet computer, a laptop, an all-in-one personal computer, a television set, and such alike.

Other systems, methods, features, advantages, objects, and further areas of applicability together with a more complete understanding of the disclosure will be, or will become, apparent and appreciated to one with skill in the art upon examination of the following figures and detailed description, or may be learned by practice of the present invention. It is intended that all such additional systems, methods, features, and advantages be included within this description, be within the scope of the present disclosure, and be protected by the following claims. Nothing in this section should be taken as a limitation on those claims.

Further aspects and advantages are discussed below in conjunction with the embodiments. It is to be understood that both the foregoing general description and the following detailed description of the present disclosure are exemplary and explanatory and are intended to provide further explanation of the disclosure as claimed, but are not intended to limit the scope of the disclosure.

### BRIEF DESCRIPTION OF THE DRAWINGS

The accompanying drawings, which are included to provide a further understanding of the disclosure and are incorporated herein and constitute a part of this application, illustrate embodiment(s) of the disclosure and together with the description serve to explain the principle of the disclosure. In the drawings:

FIG. 1A illustrates a side view of a first embodiment of a joint means in a flat out configuration;

FIG. 1B illustrates a side view of the joint means shown in FIG. 1A in a folded configuration;

FIG. 1C illustrates a side view of the joint means shown in FIG. 1A in a bent configuration;

FIG. 2A illustrates a side view of a second embodiment of a joint means in a flat out configuration;

FIG. 2B illustrates a side view of the joint means shown in FIG. 2A in a folded configuration;

FIG. 2C illustrates a side view of the joint means shown in FIG. 2A in a bent configuration;

FIG. 3A illustrates a side view of a third embodiment of a flexible device housing in a folded configuration;

FIG. 3B illustrates a side view of the third embodiment of the flexible device housing shown in FIG. 3A in a bent configuration;

FIG. 4A illustrates a side view of a fourth embodiment of a flexible device housing in a folded configuration;

FIG. 4B illustrates a side view of the fourth embodiment of the flexible device housing shown in FIG. 4A in a flat out configuration;

FIG. 5A illustrates a top view of an example portable flexible computing device according to a fifth embodiment;

FIG. 5B illustrates a side view of a portion of the example portable flexible computing device shown in FIG. 5A laying out flat;

FIG. 5C illustrates a side view of the example portable flexible computing device shown in FIG. 5A being folded;

FIG. 6A illustrates a side view of a sixth embodiment of a flexible device housing with a flexible shell covering the joint means; and

FIG. 6B illustrates a sectional view of the flexible device housing along the line A-A′ shown in FIG. 6A.

### DETAILED DESCRIPTION OF THE INVENTION

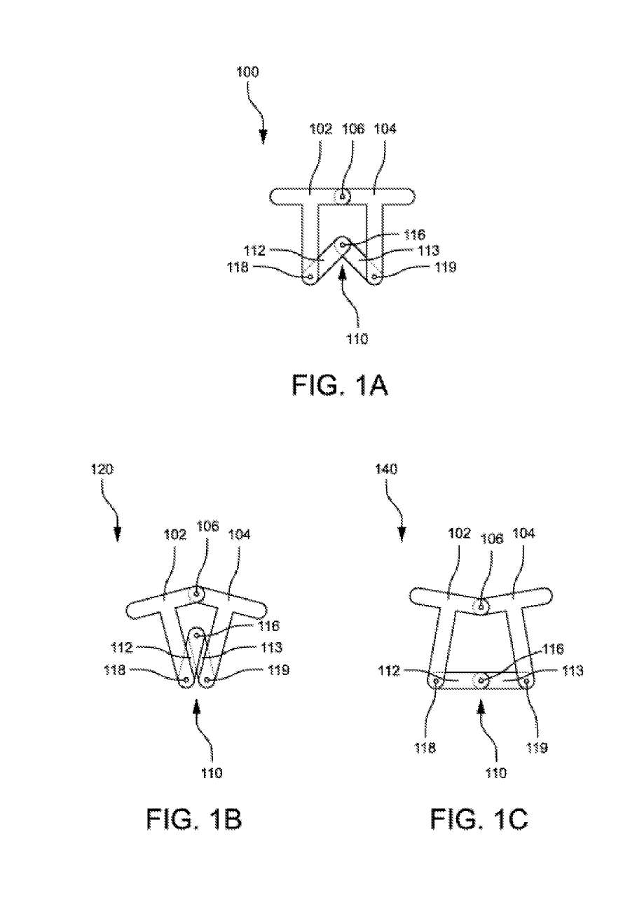

FIGS. 1A, 1B, and 1C illustrate an example of a basic joint means of a flexible device housing according to a first embodiment. The joint means comprises a first supporting element 102 and a second supporting element 104, which are shaped as T-pieces, and a third element 110. The third element 110 comprises a first member 112 and a second member 113, and is a hinge that is foldable respectively pivotable around the pivot 116. The supporting elements 102, 104 are a hinged means at their first sides, that is pivotable around the pivot 106, and are connected at their second sides by the third element 110, that is pivotable around the pivots 118, 119.

FIG. 1A shows the joint means with the third element in a flat out configuration 100, FIG. 1B shows the joint means with the third element in a folded configuration 120, and FIG. 1C shows the joint means with the third element in a bent configuration 140. As it can be seen in this example, the curvature radii of the folding and bending directions depend on the dimensions and shape of the supporting elements 102, 104 and of the third element 110. As would be apparent to one of ordinary skill in the art of geometry, the folding and bending angles depending on the dimensions of these joint elements can be determined by adjusting the dimensions in accordance to requirements on the flexible device housing.

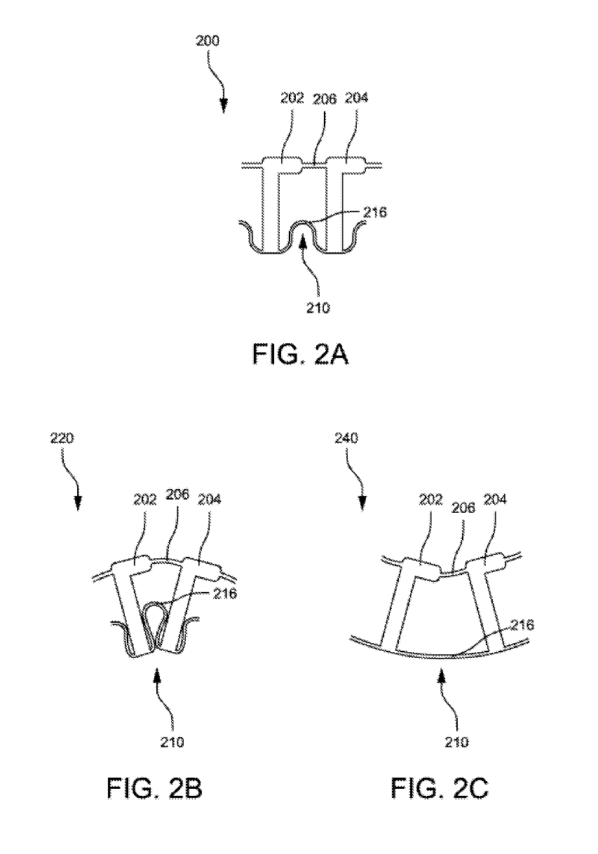

FIGS. 2A, 2B, and 2C illustrate an example of a basic joint means of a flexible device housing according to a second embodiment. The joint means comprises a first supporting element 202 and a second supporting element 204, which are shaped as L-pieces, and a third element 210. The third element 210 is a film hinge or living hinge 216. The supporting elements 202, 204 are a film hinge or living hinge at their first sides, that is bendable or pivotable around the section 206, and are connected at their second sides by the third element 210 respectively the film hinge 216.

FIG. 2A shows the joint means with the third element in a flat out configuration 200, FIG. 2B shows the joint means with the third element in a folded configuration 220, and FIG. 2C shows the joint means with the third element in a bent configuration 240. As it can be seen in this example as well, the curvature radii of the folding and bending directions depend on the dimensions and shape of the supporting elements 202, 204 and of the third element 210. As would be apparent to one of ordinary skill in the art of geometry, the folding and bending angles depending on the dimensions of these joint elements can be determined by adjusting the dimensions in accordance to requirements on the flexible device housing.

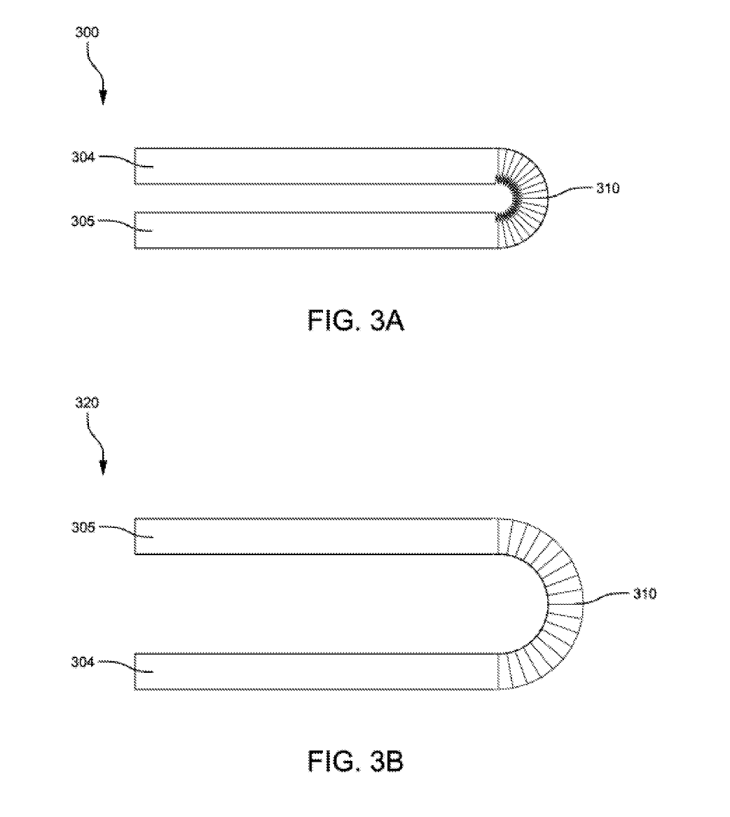

In order to provide various functionality described herein, FIGS. 3A and 3B illustrate an example of a flexible device housing according to a third embodiment. The flexible device housing comprises a first housing segment 304 and a second housing segment 305, which are connected by a foldable joint means 310. FIG. 3A shows the joint means with the third element in a folded configuration and FIG. 3B shows the joint means with the third element in a bent configuration.

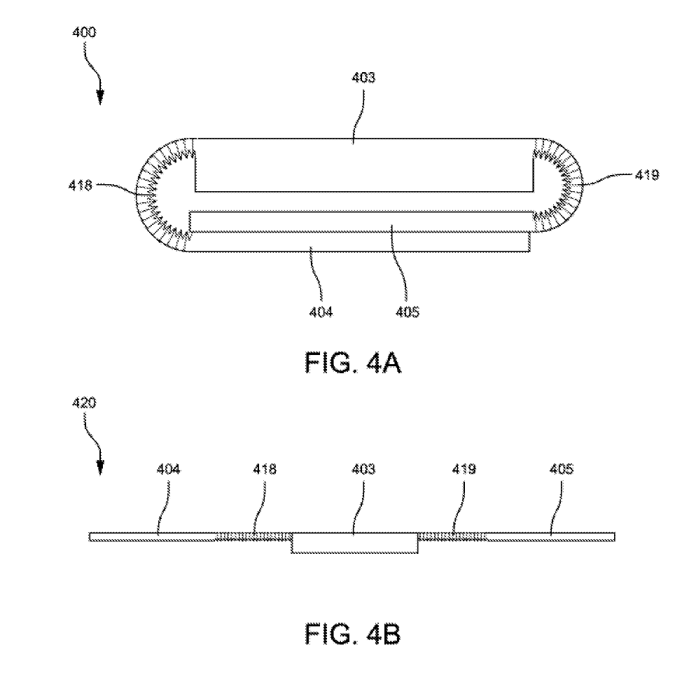

FIGS. 4A and 4B illustrate an example of a flexible device housing according to a fourth embodiment. The flexible device housing comprises a first housing segment 403, a second housing segment 404, and a third housing segment 405, which are connected by foldable joint means 418, 419. FIG. 4A shows the joint means with the third elements in a folded configuration and FIG. 4B shows the joint means with the third elements in a flat out configuration.

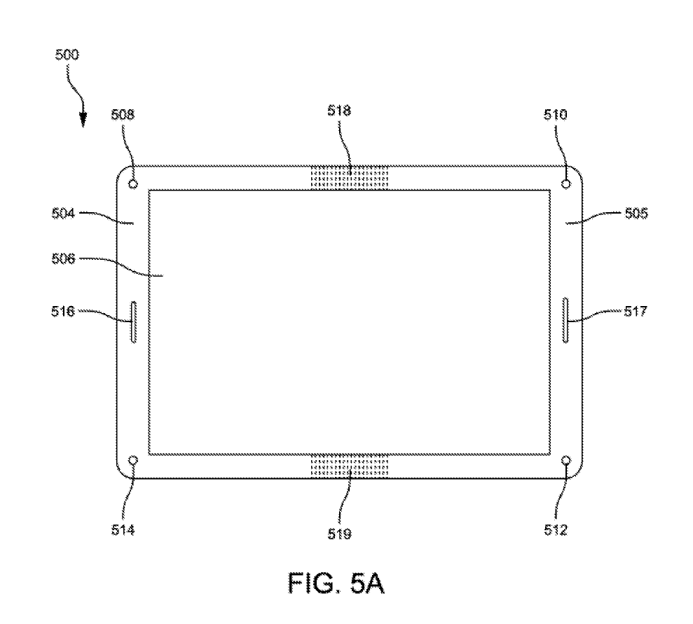

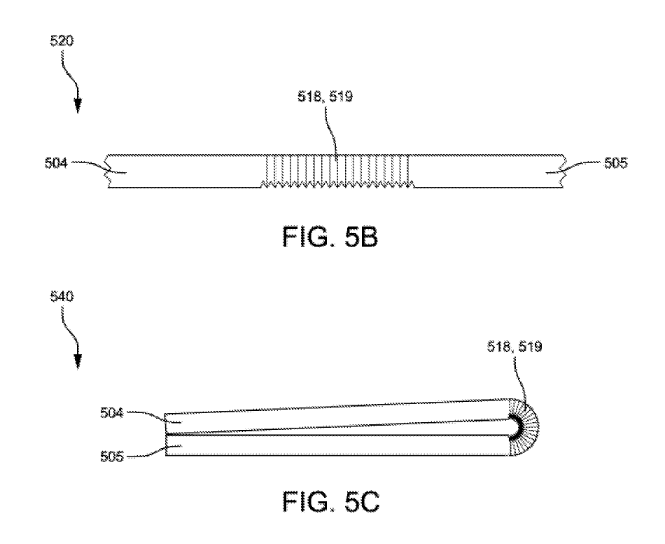

FIGS. 5A, 5B, and 5C illustrate an example portable computing device with a flexible housing and a flexible electronic visual display device according to a fifth embodiment that can be used to provide functions in accordance with various embodiments discussed and suggested herein. In this example, the portable flexible computing device has a housing comprising two segments 504, 505, bellows-like joint means 518, 519 mechanically connecting the segments 504, 505 with each other, a flexible display screen 506, four information capture elements 508, 510, 512, 514 positioned at various locations on the same side of the portable flexible computing device as the flexible display screen 506, and integrated dual-array microphones and speakers 516, 517 enabling the portable flexible computing device to capture sensor information about a user of the electronic device during typical operation where the user is at least partially in front of the flexible electronic visual display screen 506, and to reproduce sound. FIG. 5A shows the portable flexible computing device in the flat laid out configuration 500 from the top, FIG. 5B shows a portion of the portable flexible computing device in the flat laid out configuration 520 from the side, and FIG. 5C shows the portable flexible computing device in the folded configuration 540 from the side.

In this example, each capture element 508, 510, 512, 514 is a camera capable of capturing image information over a visible or/and infrared (IR) spectrum, and in at least some embodiments can select between visible and IR operational modes. It should be understood, however, that there can be fewer or additional elements of similar or alternative types in other embodiments, and that there can be combinations of cameras, infrared detectors, sensors, and other such elements used with various devices. The device can also have a material and/or components that enable a user to provide input to the device by applying pressure at one or more locations. The device housing segments 504, 505 can also include touch-sensitive material that enables a user to provide input by sliding a finger or other object along a portion of the housing. Various other elements and combinations of elements can be used as well within the scope of the various embodiments as should be apparent in light of the teachings and suggestions contained herein.

In modifications of the example portable computing device with a flexible housing and a flexible electronic visual display device according to the fifth embodiment the housing can have an adjustment means to keep the joint means 518, 519 or the whole flexible housing in a specific configuration as preconfigured or chosen by a user. Such an adjustment means can be constructed in various ways by a person ordinarily skilled in the art and therefore is not discussed further herein. Some example adjustment means are described in the U.S. Pat. No. 7,450,107, issued Nov. 11, 2009, and entitled “Bracelet with information display and inputting capability”, which is hereby incorporated by reference in its entirety.

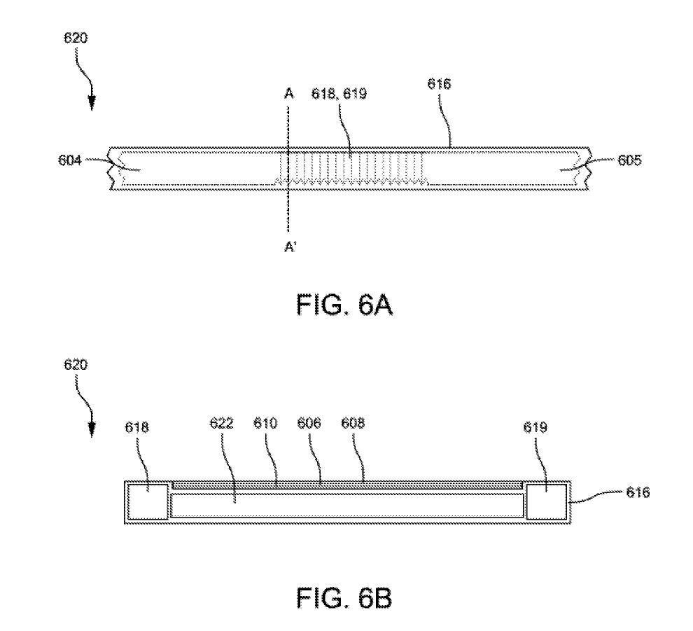

FIGS. 6A and 6B illustrate an example portable computing device with a flexible housing and a flexible electronic visual display device, such as the device shown in FIG. 5A for example, according to a sixth embodiment of the flexible device housing that can be used to provide functions in accordance with various embodiments discussed and suggested herein. In this example, the portable flexible computing device has a housing comprising two segments 604, 605, bellows-like joint means 618, 619 mechanically connecting the segments 604, 605 with each other, a flexible display screen 606 with a protection layer 608 and a support layer 610 made of a flexible material, and a flexible shell 616 covering the electronic components of the portable computing device and providing protection against dust and moisture, as well as mechanical impacts.

FIG. 6A shows a portion of the portable flexible computing device in the flat laid out configuration 620 from the side and FIG. 6B shows a sectional view of the portion of the portable computing device along the line A-A shown in FIG. 6A. In this view the area or passage 622 within the flexible housing can be seen, which is configured to contain the electronic components of a portable computing device, which can comprise solid and flexible hardware components, and to assure a sealed passage of conductors from one segment to another segment of the flexible housing.

The specification and drawings are to be regarded in an illustrative rather than a restrictive sense. It will, however, be evident that various modifications and changes may be made thereunto by those skilled in the art without departing from the broader spirit and scope of the invention as set forth in the claims. In other words, although embodiments have been described with reference to a number of illustrative embodiments thereof, this disclosure is not limited to those. Accordingly, in various embodiments of the invention the various embodiments of the joint means, flexible device housing, and portable computing device discussed and suggested in FIGS. 1A, 1B, 1C, 2A, 2B, 2C, 3A, 3B, 4A, 4B, 5A, 5B, 5C, 6A, and 6B can be combined with each other in appropriate ways. The scope of the present disclosure shall be determined only by the appended claims and their equivalents. In addition, variations and modifications in the component parts, arrangements, or/and alternative uses must be regarded as included in the appended claims.

1. A flexible electronic device housing, comprising
a mounting means for a flexible display device;
at least two housing segments configured to house electronic components;
at least one joint means for mechanically connecting two adjacent housing segments, said joint means comprising:
a first supporting element,
a second supporting element, and
a third element being a folding means,
wherein said first and second supporting elements each have a first side and a second side, said first sides are opposite to said second sides and are the sides of the mounting means for a flexible display deivce,
wherein said first and second supporting elements are connected by a hinged means at their first sides and by said third element at their second sides, and
wherein the closing angle, opening angle, and the curvature radii of the housing are determined by the dimensions of the length and the width of the first and second supporting elements and of the third element.

2. The flexible electronic device housing according to claim 1,
wherein each joint means does not project beyond a side of a housing segment.

3. The flexible electronic device housing according to claim 1,
wherein at least one supporting element of the joint means is a T-piece.

4. The flexible electronic device housing according to claim 1,
wherein at least one supporting element of the joint means is an L-piece.

5. The flexible electronic device housing according to claim 1,
wherein at least one joint means between two housing segments is a bellows with the first and second supporting elements being the sides of said bellows and the third element being shaped as the pleated element of said bellows connecting the first and second supporting elements.

6. The flexible electronic device housing according to claim 1,
wherein the hinged means connecting two adjacent supporting elements of the joint means is made of a flexible material being fastened to the supporting elements appropriately.

7. The flexible electronic device housing according to claim 1,
wherein two adjacent supporting elements of the joint means are a hinged means themselves at their first sides.

8. The flexible electronic device housing according to claim 7,
wherein the hinged means is one of (a) a folding hinge, (b) a folding piano hinge, and (c) a living hinge or film hinge.

9. The flexible electronic device housing according to claim 1,
wherein the third element of the joint means is made of a flexible material being fastened to the supporting elements appropriately.

10. The flexible electronic device housing according to claim 1,
wherein the third element of the joint means is one of (a) a folding hinge, (b) a folding piano hinge, and (c) an accordion pleat-like living hinge or accordion pleat-like film hinge.

11. The flexible electronic device housing according to claim 1, further comprising:
a shell being made of a flexible material, and being configured to cover the joint means and electronic components of a flexible electronic device contained within the flexible housing.

12. The flexible electronic device housing according to claim 1,
wherein the supporting elements of the joint means are the housing segments.

13. The flexible electronic device housing according to claim 1,
wherein the one or more joint means between the housing segments are dimensioned in such a way that the housing segments at the sides touch each other when the flexible housing is in a folded or bent configuration.

14. The flexible electronic device housing according to claim 1,
wherein the first and second supporting elements and the third element of the joint means are dimensioned in such a way that the angle of rotation is limited to 180 degree.

15. The flexible electronic device housing according to claim 1, further comprising:
at least one adjustment means for keeping at least one joint means of the housing in at least one configuration.

16. The flexible electronic device housing according to claim 15, further comprising:
at least one shape-memorizing element being configured to memorize the curvature of at least one joint means of the housing for keeping said at least one joint means in its last configuration.

17. The flexible electronic device housing according to claim 1, further comprising:
at least one spring for keeping at least one joint means of the housing in at least one configuration.
